(19) United States
(12) Patent Application Publication
(10) Pub. No.: US 2013/0049094 A1
(43) Pub. Date: Feb. 28, 2013

(54) NON-VOLATILE MEMORY DEVICE AND METHOD FOR FABRICATING THE SAME

(71) Applicant: Jae-Soon KWON, Gyeonggi-do (KR)

(72) Inventor: Jae-Soon KWON, Gyeonggi-do (KR)

(21) Appl. No.: 13/333,988

(22) Filed: Dec. 21, 2011

(30) Foreign Application Priority Data
Aug. 25, 2011 (KR) 10-2011-0085129

(51) Int. Cl. H01L 29/788; H01L 21/336

(52) U.S. Cl. 257/321; 438/264; 257/E29.3; 257/E21.422

(57) ABSTRACT

A method for fabricating a non-volatile memory device includes forming a gate layer over a substrate having a cell region and a peripheral circuit region, forming a gate pattern corresponding to a region for selection lines and a region between neighboring selection lines in the cell region, where during the forming of the gate pattern, word lines in the cell region and a peripheral circuit gate in the peripheral circuit region are formed by selectively etching the gate layer, forming spacers on sidewalls of the peripheral circuit gate, and forming the selection lines by selectively etching a portion of the gate pattern corresponding to the region between the neighboring selection lines.

### CROSS-REFERENCE TO RELATED APPLICATIONS

The present application claims priority of Korean Patent Application No. 10-2011-0085129, filed on Aug. 25, 2011, which is incorporated herein by reference in its entirety.

### BACKGROUND

1. Field

Exemplary embodiments of the present invention relate to a non-volatile memory device and a fabrication method thereof, and more particularly, to a non-volatile memory device including transistors formed in a cell region and a peripheral region, and a method for fabricating the non-volatile memory device.

2. Description of the Related Art

Non-volatile memory devices are memory devices that retain data stored therein although a power supply is cut off. An example of the non-volatile memory devices is a NAND-type flash memory device with a plurality of memory cells grouped into strings, where the strings of memory cells are controlled collectively and high integration of memory devices is achieved.

A NAND-type flash memory device includes a plurality of strings disposed in a cell region, and each string includes a drain selection transistor, a plurality of memory cells, and a source selection transistor that are coupled with each other in series. Here, the strings coupled to ends of each other have a symmetrical structure to each other. Also, the NAND-type flash memory device includes diverse unit devices disposed in a peripheral circuit region, such as a peripheral circuit transistor.

Meanwhile, when the NAND-type flash memory device is fabricated, a drain selection line, source selection line and word lines disposed in the cell region and a gate disposed in the peripheral circuit region are simultaneously patterned in general. Subsequently, a process of forming an oxide layer having a sufficient thickness to fill the space between word lines, a process of forming spacers on the sidewalls of a peripheral circuit gate to realize a Lightly Doped Drain (LDD) structure in a peripheral circuit transistor, and a process of forming a buffer oxide layer and a nitride layer are sequentially performed.

Here, the process of forming spacers on the peripheral circuit gate is performed by forming a spacer-forming insulation layer that covers the cell region and the peripheral circuit region and subsequently performing a blanket etch process on the spacer-forming insulation layer. Thus, a sidewall structure similar to a spacer is undesirably formed on one sidewall of the source selection line and one sidewall of the drain selection line along with the spacers on the sidewalls of the peripheral circuit gate. The formation of the sidewall structure greatly decreases the space between neighboring drain selection lines, which is a space where a drain contact is to be formed, and the space between neighboring source selection lines, which is a space where a source contact is to be formed, and the decrease in the spaces becomes more pronounced in the subsequent processes of forming a buffer oxide layer and a nitride layer.

In summary, the conventional method of fabricating a non-volatile memory device increases the procedural difficulty of the process of forming a drain contact and the process of forming a source contact, and accordingly, the possibility of failure such as Contact-Not-Open increases as well. Also, since the widths of the drain contact and the source contact are decreased, contact resistance may increase.

### SUMMARY

An embodiment of the present invention is directed to a non-volatile memory device that may have decreased contact resistance, decreased procedural difficulty, and decrease the occurrence of failure by sufficiently securing the space where a drain contact and/or a source contact are to be formed in a cell region, and a method for fabricating the non-volatile memory device.

In accordance with an embodiment of the present invention, a method for fabricating a non-volatile memory device includes: forming a gate layer over a substrate having a cell region and a peripheral circuit region; forming a gate pattern corresponding to a region for selection lines and a region between neighboring selection lines in the cell region, where during the forming of the gate pattern, word lines in the cell region and a peripheral circuit gate in the peripheral circuit region are formed by selectively etching the gate layer; forming spacers on sidewalls of the peripheral circuit gate; and forming the selection lines by selectively etching a portion of the gate pattern corresponding to the region between the neighboring selection lines.

In accordance with another embodiment of the present invention, a non-volatile memory device includes: a substrate including a cell region and a peripheral circuit region; word lines and selection lines formed in the cell region of the substrate; a first sidewall structure disposed on two sidewalls of a pair of neighboring selection lines; a peripheral circuit gate formed in the peripheral circuit region of the substrate; and a second sidewall structure disposed on sidewalls of the peripheral circuit gate, wherein the first sidewall structure is thinner than the second sidewall structure.

### BRIEF DESCRIPTION OF THE DRAWINGS

FIG. 1 is a plan view illustrating a non-volatile memory device in accordance with an embodiment of the present invention.

FIGS. 2A to 2H are cross-sectional views illustrating a method for fabricating a non-volatile memory device in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

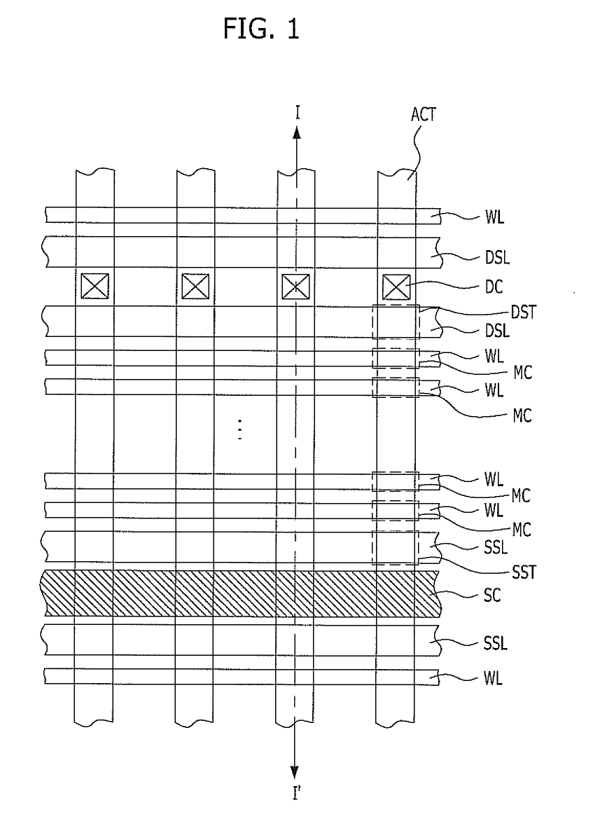

FIG. 1 is a plan view illustrating a non-volatile memory device in accordance with an embodiment of the present invention. The drawing shows a cell region.

Referring to FIG. 1, an active region ACT formed over a semiconductor substrate has a shape stretched in one direction and a plurality of active regions ACT are arrayed in parallel to each other. Hereafter, for illustration purposes, the direction that the active regions ACT are stretched is referred to as a first direction, and the direction crossing the first direction is referred to as a second direction.

A drain selection line DSL, word lines WL, and a source selection line SSL that are stretched in the second direction crossing the active regions ACT are arrayed in parallel to each other over the semiconductor substrate. In particular, a plurality of word lines WL are disposed between one drain selection line DSL and one source selection line SSL. Junction regions are formed in the active regions ACT between the drain selection line DSL, the word lines WL, and the source selection line SSL. The drain selection line DSL overlapping one active region ACT and the junction regions on either sides of the drain selection line DSL constitute a drain selection transistor DST, and the source selection line SSL overlapping one active region ACT and the junction regions on either sides of the source selection line SSL constitute a source selection transistor SST. Each word line WL overlapping one active region ACT and the junction regions on either sides of the word line WL constitute a memory cell MC.

The drain selection transistor DST, a plurality of memory cells MC, and the source selection transistor SST are serially coupled with each other to form a unit string. As illustrated in the drawing, there are a plurality of strings, and the strings are arrayed in the first direction and the second direction. Here, any one string, which is referred to as a first string, and another string, which is referred to as a second string, that is adjacent to the first string in the first direction has a symmetrical structure to the structure of the first string. For example, when it is assumed that the first string has a structure where the source selection line SSL is disposed in the lowermost part and the drain selection line DSL is disposed in the uppermost part, the drain selection line DSL of a string disposed over the first string is disposed in the lowermost part and the source selection line SSL of a string disposed below the first string is disposed in the uppermost part. As a result, the drain selection line DSL of the first string and the drain selection line DSL of the string over the first string are adjacent to each other, and the source selection line SSL of the first string and the source selection line SSL of the string below the first string are adjacent to each other.

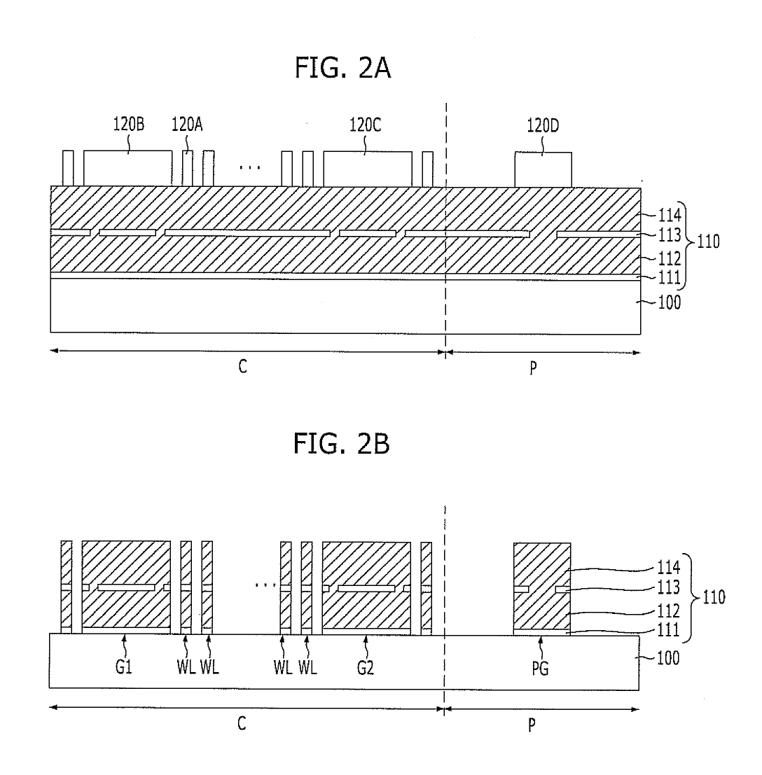

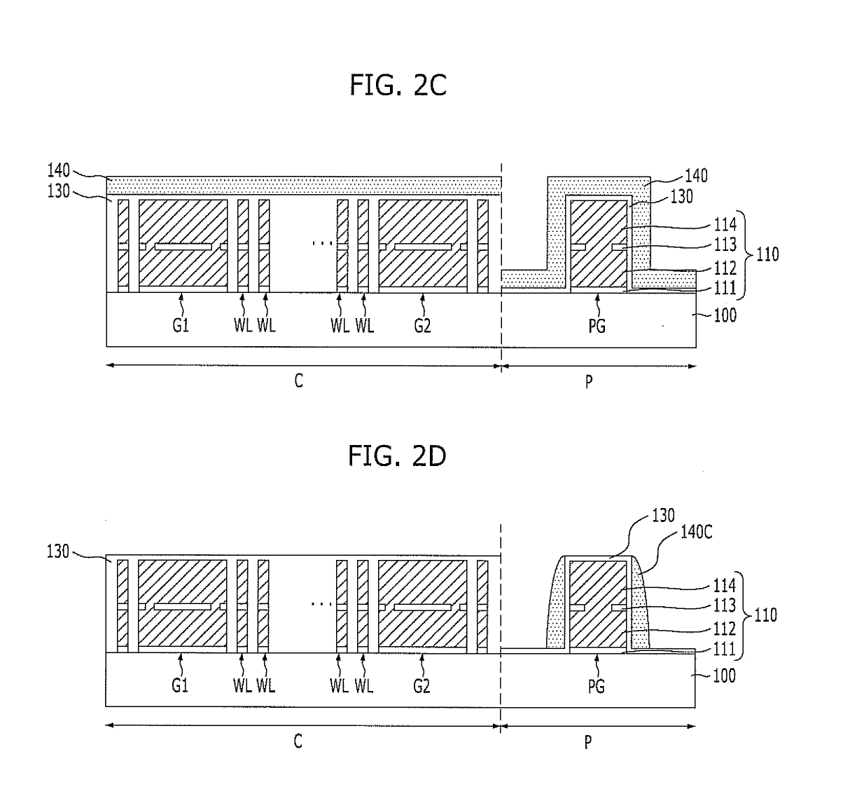

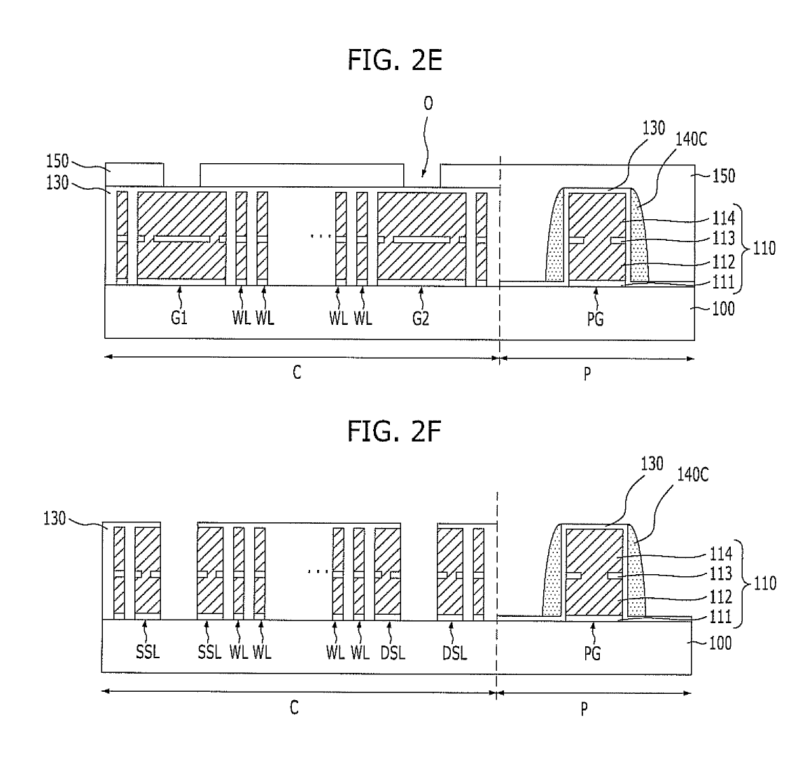

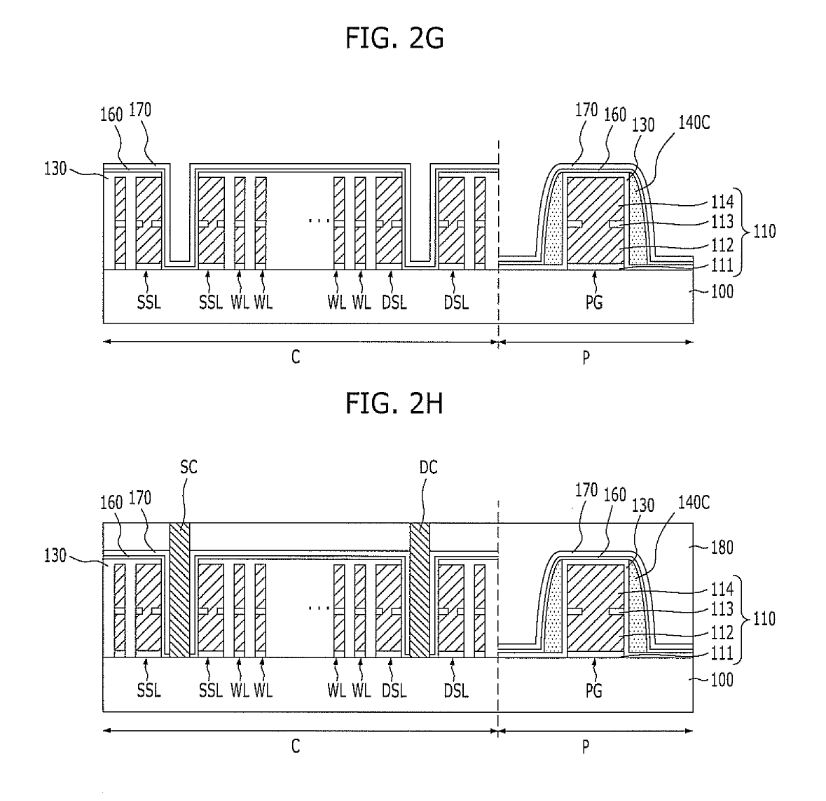

A drain contact DC is formed over the active region ACT between neighboring drain selection lines DSLs, coupling a drain region of a drain selection transistor DST with a line (not shown in the drawing) such as a bit line. Also, a line-type source contact SC is formed over the semiconductor substrate between neighboring source selection lines SSLs, coupling a source region of a source selection transistor SST with a line (not shown in the drawing) such as a source line. Here, the shapes of the drain contact DC and the source contact SC are not limited to the shapes shown in the drawing and they may be modified differently. Since the drain contact DC and the source contact SC are formed between neighboring drain selection lines DSLs and between neighboring source selection lines SSLs, respectively, the space between the neighboring drain selection lines DSLs and the space between the neighboring source selection lines SSLs are to be adequately secured. A method for fabricating a non-volatile memory device that is secured with the space between the neighboring drain selection lines DSLs and the space between the neighboring source selection lines SSLs is described in detail below with reference to FIGS. 2A to 2H.

FIGS. 2A to 2H are cross-sectional views illustrating a method for fabricating a non-volatile memory device in accordance with an embodiment of the present invention. The cross-sectional views simultaneously show a cell region and a peripheral circuit region of the non-volatile memory device. Particularly, the cell region is a cross-sectional view obtained by cutting the non-volatile memory device along a I-I′ line.

Referring to FIG. 2A, a substrate 100 having a cell region C and a peripheral circuit region P is provided. Here, the substrate 100 may include an isolation layer formed through a Shallow Trench Isolation (STI) process and an active region defined by the isolation layer.

Subsequently, a gate layer 110 for forming a drain selection line DSL, word lines WL, and a source selection line SSL in the cell region C and forming a gate of a peripheral circuit transistor, which is referred to as a peripheral circuit gate hereafter, in the peripheral circuit region P is formed over the substrate 100.

The gate layer 110 may include a tunnel insulation layer 111, a floating gate layer 112, a charge blocking layer 113, and a control gate layer 114 that are sequentially stacked. If any, the entire or part of the charge blocking layer 113 may be removed in a region where the drain selection line DSL and the source selection line SSL are to be formed and a region where the peripheral circuit gate is to be formed, and accordingly, the floating gate layer 112 and the control gate layer 114 may be electrically conducted with each other in the corresponding region.

The tunnel insulation layer 111 may be an oxide layer, and the floating gate layer 112 may be a polysilicon layer. The charge blocking layer 113 may be an oxide-nitride-oxide (ONO) layer, and the control gate layer 114 may be a metal layer, a metal silicide layer or a double layer including, for example, a polysilicon layer and a metal silicide layer.

Subsequently, a first mask pattern 120A, 12013, 120C and 120D that cover a region where word lines WL are to be formed (see ‘120A’), a region where neighboring source selection lines SSLs are to be formed and a region between the neighboring source selection lines SSLs (see ‘120B’), a region where neighboring drain selection lines DSLs are to be formed and a region between the neighboring drain selection lines DSLs (see ‘120C’) and a region where the peripheral circuit gate is to be formed (see ‘120D’) is formed over the gate layer 110. The first mask pattern 120A, 120B, 120C and 120D may be a photoresist pattern, or it may be a hard mask pattern such as a nitride layer that is patterned using a photoresist pattern.

Referring to FIG. 2B, a peripheral circuit gate PG is formed in the peripheral circuit region P while forming word lines WL in the cell region C by etching the gate layer 110 using the first mask pattern 120A, 120B, 120C and 120D as an etch barrier. Here, each word line WL includes a stacked structure of the tunnel insulation layer 111, the floating gate layer 112, the charge blocking layer 113, and the control gate layer 114 that is etched using a mask pattern 120A. Also, the peripheral circuit gate PG includes a stacked structure of the tunnel insulation layer 111, the floating gate layer 112, the charge blocking layer 113, and the control gate layer 114 that is etched using a mask pattern 120D, where a portion of the charge blocking layer 113 is removed in the region between the floating gate layer 112 and the control gate layer 114. Despite the features of the illustration in the drawing, the charge blocking layer 113 may be omitted from the peripheral circuit gate PG, and in this case, the floating gate layer 112 and the control gate layer 114 may contact each other across the entire surface.

Herein, while the word lines WL and the peripheral circuit gate PG are formed, a first gate pattern G1 is formed corresponding to the region where neighboring source selection lines SSLs are to be formed and the region between the neighboring source selection lines SSLs by using a mask pattern 120B of the cell region C as an etch barrier and etching the gate layer 110, and a second gate pattern G2 is formed corresponding to the region where neighboring drain selection lines DSLs are to be formed and the region between the neighboring drain selection lines DSLs by using a mask pattern 120C of the cell region C as an etch barrier and etching the gate layer 110. The first gate pattern G1 is a stacked structure of the tunnel insulation layer 111, the floating gate layer 112, the charge blocking layer 113, and the control gate layer 114 that is etched using the mask pattern 120B. Particularly, the entire or part of the charge blocking layer 113 is removed in the region where the source selection line SSL is to be formed. The second gate pattern G2 is a stacked structure of the tunnel insulation layer 111, the floating gate layer 112, the charge blocking layer 113, and the control gate layer 114 that is etched using the mask pattern 120C. Particularly, the entire or part of the charge blocking layer 113 is removed in the region where the drain selection line DSL is to be formed.

In this embodiment of the present invention, the drain selection line DSL and the source selection line SSL are not formed together while the word lines WL and the peripheral circuit gate PG are formed simultaneously.

Referring to FIG. 2C, a first insulation layer 130 is formed over the resultant substrate structure of FIG. 2B in a thickness filling the space between the word lines WL, the space between the word lines WL and the first gate pattern G1, and the space between the word lines WL and the second gate pattern G2. Here, while the space between the word lines WL, the space between the word lines WL and the first gate pattern G1, and the space between the word lines WL and the second gate pattern G2 are narrow, the patterns of the peripheral circuit region P, such as the peripheral circuit gate PG, are relatively big in size and disposed with a relatively low density. Therefore, the first insulation layer 130 of the peripheral circuit region P is formed along the profile of the peripheral circuit gate PG. Here, the first insulation layer 130 functions to prevent the interference between neighboring word lines WL. The first insulation layer 130 may be an oxide layer.

Subsequently, a second insulation layer 140 is formed over the first insulation layer 130. The second insulation layer 140 is for forming spacers on the sidewalls of the peripheral circuit gate PG, and the second insulation layer 140 may be an oxide layer.

Referring to FIG. 2D, spacers 140C are formed on the sidewalls of the peripheral circuit gate PG with the first insulation layer 130 between the spacers 140C and the peripheral circuit gate PG by performing a blanket etch process on the second insulation layer 140 until the upper surface of the first insulation layer 130 is exposed.

Herein, the spacers 140C are formed on the sidewalls of the peripheral circuit gate PG to form a Lightly Doped Drain (LDD) structure in a peripheral circuit transistor. The LDD structure may be formed by doping the substrate 100 exposed by the peripheral circuit gate PG with a low-concentration N-type impurity before the formation of the spacers 140C and doping the substrate 100 exposed by the spacers 140C with a high-concentration N-type impurity after the formation of the spacers 140C. With the LDD structure, the characteristics of the peripheral circuit transistor such as current driving capability or hot-carrier features may be improved.

Since the first insulation layer 130 fills all the spaces of the cell region C, e.g., the space between the word lines WL, the space between the word lines WL and the first gate pattern G1, the space between the word lines WL and the second gate pattern G2, in the stage of forming the spacers 140C, a sidewall structure having a similar shape to the shape of the spacers 140C is not formed in the cell region C.

Referring to FIG. 2E, a second mask pattern 150 having an opening O that exposes the space between the regions where neighboring source selection lines SSLs are to be formed and the space between the regions where neighboring drain selection lines DSLs are to be formed is formed over the resultant substrate structure of FIG. 2D. The second mask pattern 150 may be a photoresist pattern or a hard mask pattern such as a nitride layer patterned using a photoresist pattern.

Referring to FIG. 2F, the first gate pattern G1 and the second gate pattern G2 that are exposed through the opening O are etched using the second mask pattern 150 as an etch barrier.

As a result of this process, the portion corresponding to the space between the source selection lines SSLs is removed from the first gate pattern G1. Thus, two neighboring source selection lines SSLs are formed. Also, since the portion corresponding to the space between the drain selection lines DSLs is removed from the second gate pattern G2, two neighboring drain selection lines DSLs are formed.

In this embodiment of the present invention described above, the spacers 140C are first formed on the sidewalls of the peripheral circuit gate PG in the peripheral circuit region P, and subsequently the drain selection line DSL and the source selection line SSL are formed. As a result, a sidewall structure having a similar shape to the shape of the spacers 140C is not formed on the sidewalls of the drain selection line DSL and the source selection line SSL during the formation of the spacers 140C. Therefore, the decrease in the space between the drain selection lines DSLs and the space between the source selection lines SSLs in the conventional technology may not occur. Accordingly, a subsequent process of forming contacts is facilitated.

Referring to FIG. 2G, a third insulation layer 160 for a buffer is formed over the resultant substrate structure of FIG. 2F. The third insulation layer 160 is a layer for reducing the stress between a fourth insulation layer, which is to be formed in a subsequent process, and the understructure of the third insulation layer 160. The third insulation layer 160 may be an oxide layer.

Subsequently, the fourth insulation layer 170 is formed over the third insulation layer 160. The fourth insulation layer 170 may serve as an etch stop layer in a subsequent process for forming drain contacts and/or source contacts, while protecting the understructure. Also, the fourth insulation layer 170 may be formed of a material having an etch selectivity against an inter-layer dielectric layer, which is to be formed in a subsequent process, so as to form drain contacts and/or source contacts using based on Self Aligned Contact formation method subsequently. For example, the fourth insulation layer 170 may be formed of a nitride layer.

Here, since the space between the drain selection lines DSLs and the space between the source selection lines SSLs are increased compared with conventional technology, the space where contacts are to be formed may be obtained sufficiently even though the fourth insulation layer 170 is formed.

Referring to FIG. 2H, an inter-layer dielectric layer 180 is formed of a material having an etch selectivity against the fourth insulation layer 170 (for example, the material formed of an oxide) over the fourth insulation layer 170.

Subsequently, the inter-layer dielectric layer 180 formed between the source selection lines SSLs and the drain selection lines DSLs is selectively etched, and the etching of the inter-layer dielectric layer 180 stops in the fourth insulation layer 170. And subsequently, the fourth insulation layer 170 and the third insulation layer 160 that are exposed as a result of selectively etching the inter-layer dielectric layer 180 are etched. As a result, openings for forming contacts that expose the substrate 100 are formed. Here, the openings for forming contacts may have a hole shape between the drain selection lines DSLs, and the openings for forming contacts may have a line shape between the source selection lines SSLs.

Subsequently, drain contacts DC coupled with the substrate 100 by penetrating between the drain selection lines DSLs and source contacts SC coupled with the substrate 100 by penetrating between the source selection lines SSLs are formed by filling the openings for forming contacts with a conductive material.

Subsequently, although not illustrated, an additional process, such as a process of forming lines respectively coupled with the drain contacts DC and the source contacts SC, e.g., bit lines and source lines, may be additionally carried out.

The device of FIG. 2H may be fabricated through the above-described fabrication method.

Referring back to FIG. 2H, the sidewall structure of the drain selection lines DSLs and the source selection lines SSLs in the cell region C and the sidewall structure of the peripheral circuit gate PG in the peripheral circuit region P are different from each other. In short, whereas the third insulation layer 160 and the fourth insulation layer 170 are disposed on the sidewall on the drain contacts DC among the sidewalls of the drain selection lines DSLs and the sidewall on the source contacts SC among the sidewalls of the source selection lines SSLs, the first insulation layer 130, the spacers 140C, the third insulation layer 160, and the fourth insulation layer 170 are disposed on sidewalls of the peripheral circuit gate PG. This is because the drain selection lines DSLs and the source selection lines SSLs are completed after the spacers 140C of the peripheral circuit gate PG are formed, as mentioned before. In this case, the process of forming the drain contacts DC and the source contacts SC becomes easier and the occurrence of failure originating from the process decreases because the space between the drain selection lines DSLs and the space between the source selection lines SSLs are sufficiently obtained. Moreover, since the areas of the drain contacts DC and the source contacts SC become wider, resistance is reduced as well.

According to an embodiment of the present invention, a non-volatile memory device may have decreased contact resistance, decreased procedural difficulty, and decreased possibility of the occurrence of failure by sufficiently securing the space where a drain contact and/or a source contact are to be formed in a cell region.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a non-volatile memory device, comprising:
forming a gate layer over a substrate having a cell region and a peripheral circuit region;
forming a gate pattern corresponding to a region for selection lines and a region between neighboring selection lines in the cell region, wherein during the forming of the gate pattern, word lines in the cell region and a peripheral circuit gate in the peripheral circuit region are formed by selectively etching the gate layer;
forming spacers on sidewalls of the peripheral circuit gate; and
forming the selection lines by selectively etching a portion of the gate pattern corresponding to the region between the neighboring selection lines.

2. The method of claim 1, wherein the gate layer comprises a stacked structure of a tunnel insulation layer, a floating gate layer, a charge blocking layer, and a control gate layer, and
at least a part of the charge blocking layer in a region where the peripheral circuit gate is to be formed and a region where the selection lines are to be formed is removed.

3. The method of claim 1, wherein the selection lines comprise a drain selection line on one side of the word lines and a source selection line on the other side of the word lines, and
the drain selection line is disposed to be adjacent to another drain selection line and the source selection line is disposed to be adjacent to another source selection line.

4. The method of claim 1, further comprising:
forming a first insulation layer having a thickness filling a space between the word lines and a space between the word lines and the gate pattern over a substrate structure after the forming of the word line, the selection lines, and the gate pattern.

5. The method of claim 4, wherein the forming of the spacers comprises:
forming a second insulation layer for forming the spacers over the first insulation layer; and
performing a blanket etch process on the second insulation layer.

6. The method of claim 1, further comprising:
forming a third insulation layer for forming a buffer and a fourth insulation layer over a substrate structure after the forming of the selection lines.

7. The method of claim 6, wherein the third insulation layer is an oxide layer and the fourth insulation layer is a nitride layer.

8. The method of claim 6, further comprising:
forming an inter-layer dielectric layer having an etch selectivity against the fourth insulation layer over the fourth insulation layer after the forming of the fourth insulation layer;
forming an opening that penetrates between the neighboring selection lines by selectively etching the inter-layer dielectric layer;
exposing the substrate by removing the fourth insulation layer and the third insulation layer on a lower surface of the opening; and
forming a contact filling the opening.

9. A non-volatile memory device, comprising:
a substrate including a cell region and a peripheral circuit region;
word lines and selection lines formed in the cell region of the substrate;
a first sidewall structure disposed on two sidewalls of a pair of neighboring selection lines;
a peripheral circuit gate formed in the peripheral circuit region of the substrate; and
a second sidewall structure disposed on sidewalls of the peripheral circuit gate,
wherein the first sidewall structure is thinner than the second sidewall structure.

10. The non-volatile memory device of claim 9, wherein the number of layers constituting the first sidewall structure is smaller than the number of layers constituting the second sidewall structure.

11. The non-volatile memory device of claim 9, wherein the second sidewall structure comprises spacers and a third insulation layer for forming a buffer and a fourth insulation layer that are formed along the spacers, and
the first sidewall structure comprises the third insulation layer and the fourth insulation layer.

12. The non-volatile memory device of claim 11, wherein the spacers each include an oxide layer, the third insulation layer is an oxide layer, and the fourth insulation layer is a nitride layer.

13. The non-volatile memory device of claim 9, wherein each of the word lines, the selection lines, and the peripheral circuit gate comprises a stacked structure of a tunnel insulation layer, a floating gate layer, a charge blocking layer, and a control gate layer, and
at least a part of the charge blocking layer of the selection lines and the peripheral circuit gate is removed.

14. The non-volatile memory device of claim 9, wherein the selection lines comprise a drain selection line on one side of the word lines and a source selection line on the other side of the word lines, and
the drain selection line is disposed adjacent to another drain selection line, and
the source selection line is disposed adjacent to another source selection line.

15. The non-volatile memory device of claim 9, further comprising:
a first insulation layer filling a space between the word lines and a space between the word lines and remaining sidewalls of the selection lines other than the two sidewalls of the selection lines.

16. The non-volatile memory device of claim 9, further comprising:
a contact coupled with the substrate and penetrating between the neighboring selection lines.

17. The non-volatile memory device of claim 9, further comprising extended layers of the first sidewall structure that extend over the two sidewalls of the pair of neighboring selection lines, over two sidewalls of another pair of neighboring selection lines, and over the top of the word lines that lie between the two pairs of neighboring selection lines.

18. The non-volatile memory device of claim 17, further comprising a dielectric layer formed over the extended layers and over the top of the word lines and placed between two contacts that are each formed between a corresponding one of the two pairs of neighboring selection lines.
